(19) United States
(12) Patent Application Publication
(10) Pub. No.: US 2012/0308788 A1
(43) Pub. Date: Dec. 6, 2012

(54) OVERLAY MARK SET AND METHOD FOR POSITIONING TWO DIFFERENT LAYOUT PATTERNS

(76) Inventors: Chui-Fu Chiu, Taoyuan City (TW); Chun-Yen Huang, Taoyuan City (TW)

(21) Appl. No.: 13/149,841

(22) Filed: May 31, 2011

(51) Int. Cl. G03F 7/20; B44C 1/17; B32B 37/02; B32B 3/10

(52) U.S. Cl. 428/201; 430/325; 156/235; 156/64

(57) ABSTRACT

An overlay mark set includes a substrate, a first overlay mark and a second overlay mark. The first overlay mark is disposed on the substrate for representing a first layout pattern. The second overlay mark is also disposed on the substrate for representing a second layout pattern. In particular, the first overlay mark is in direct contact with the second overlay mark.

### BACKGROUND OF THE INVENTION

1. Field of the Invention

The present invention generally relates to an overlay mark set and a method for positioning two different layout patterns. In particular, the present invention is directed to an overlay mark set in which a first overlay mark is indirect contact with a second overlay mark when the overlay mark set is in use for positioning two different layout patterns on a same surface of a substrate. The present invention is also directed to a method for positioning two different layout patterns on a same surface of a substrate by using an overlay mark set in which a first overlay mark is able to be indirect contact with a second overlay mark when the overlay mark set is in use.

2. Description of the Prior Art

Semiconductor integrated circuits undergo a variety of processing steps during their manufacture, such as masking, resist coating, etching, and deposition. In many of these steps, material is overlaid or removed from the existing layer at specific locations in order to form the desired elements of the integrated circuit. Proper overlay of the various process layers is therefore critical. The shrinking dimensions of modern integrated circuits require more and more stringent overlay accuracy during the pattern transfer step. If the expected overlay tolerance is not met, the adverse result is a device that is defective or has reliability problems.

Registration is typically used to measure the accuracy of a process layer overlay performed using an overlay mark. Registration involves comparing the position of a subsequent layer to that of an existing layer by overlaying a distinct pattern on a matching pattern previously formed on the existing layer. The deviation in position of the overlay from the original provides a measure of accuracy of the overlay. Currently available registration structures include box-in-box visual verniers to determine the amount of overlay offset. A conventional overlay mark set of the box-in-box type usually includes two different overlay marks. The inner and outer overlay marks for, respectively, the previous layer and the current layer do not contact each other.

When the conventional overlay mark set is used, a first overlay mark and a second overlay mark in the conventional overlay mark set are respectively disposed in two different layers on the substrate. The bottom overlay mark (the first overlay mark for instance) is formed along with a previous pattern beneath the second overlay mark. The top overlay mark (the second overlay mark for example) is formed along with a current pattern on top of the first overlay mark and without directly contacting the first overlay mark. The two overlay marks may vertically form a box-in-box pattern to indicate the misalignment between the previous pattern and the current pattern. The conventional overlay mark set is not suitable for positioning two different layout patterns on a same surface of a substrate accordingly.

Therefore, when it comes to positioning two different layout patterns on a same surface of a substrate, a novel overlay mark set as well as novel method are still needed.

### SUMMARY OF THE INVENTION

Given the above, the present invention in a first aspect proposes a novel overlay mark set for positioning two different layout patterns on a same surface of a substrate. In particular, the two overlay marks may be in direct contact with each other when in use. The present invention also proposes a method for positioning two different layout patterns on a same surface of a substrate by using an overlay mark set in which a first overlay mark and a second overlay mark may be formed on the same surface of the substrate.

The overlay mark set of the present invention includes a substrate, a first overlay mark and a second overlay mark. The first overlay mark is disposed on the substrate for representing a first layout pattern. The second overlay mark is also disposed on the substrate for representing a second layout pattern. In particular, the first overlay mark is in direct contact with the second overlay mark.

In one embodiment of the present invention, the first layout pattern is disposed on the substrate and the second layout pattern is disposed on the same substrate.

In another embodiment of the present invention, the first layout pattern includes a plurality of first segments and the second layout pattern includes a plurality of second segments. The first segments and the second segments are disposed in an alternate fashion.

In another embodiment of the present invention, the first overlay mark represents a previous layout pattern.

In another embodiment of the present invention, the second overlay mark represents a current layout pattern.

In another embodiment of the present invention, the second overlay mark is higher than the first overlay mark.

In another embodiment of the present invention, the first overlay mark is a polygon.

In another embodiment of the present invention, the first overlay mark is oval.

In another embodiment of the present invention, the second overlay mark is a polygon.

In another embodiment of the present invention, the second overlay mark is oval.

The present invention in a second aspect proposes a novel method for positioning two different layout patterns on the same surface. First, a substrate is provided. Second, a first layout pattern and a first overlay mark are formed on the substrate. The first overlay mark is processed, and a second layout pattern and a second overlay mark are formed on the substrate so that the second overlay mark is indirect contact with the first overlay mark. Then, the second layout pattern is positioned and compared with the first overlay mark.

In one embodiment of the present invention, the formation of the first layout pattern and the first overlay mark on the substrate includes the following steps. First, a first material layer is formed on the substrate. The first layout pattern is transferred into the first material layer by exposure and development.

In another embodiment of the present invention, the processing of the first overlay mark includes hard-baking the first overlay mark.

In another embodiment of the present invention, the formation of the second layout pattern and the second overlay mark on the substrate includes the following steps. First, a second material layer is formed on the substrate so that the second material layer covers the first layout pattern. Then, the second layout pattern is transferred into the second material layer by exposure and development.

In another embodiment of the present invention, the first layout pattern and the second layout pattern are disposed in alternate order.

In another embodiment of the present invention, the method for positioning two layout patterns further includes the step of positioning the first overlay mark.

In another embodiment of the present invention, the step of positioning the first overlay mark includes recording the position of the first overlay mark digitally.

In another embodiment of the present invention, the step of positioning the first overlay mark includes taking an image of the first overlay mark.

In another embodiment of the present invention, the step of positioning the second overlay mark may include the following stages. First, the position of the second overlay mark and the first overlay mark is recorded digitally together. Then, the position of the second overlay mark and the first overlay mark is compared with the position of the first overlay mark alone.

In another embodiment of the present invention, the step of positioning the second overlay mark may include the following stages. First, an image of the first overlay mark and the second layout pattern together is taken. Then, the image of the first overlay mark and the second overlay mark is compared with the image of the first overlay mark alone.

In another embodiment of the present invention, the step of positioning the second overlay mark may include the following stages. First, the first overlay mark and the second overlay mark together are detected optically to obtain optical data. Then, the optical data is resolved to respectively position the first overlay mark and the second overlay mark.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 illustrate the overlay mark set of the present invention.

FIGS. 3-11 illustrate the methods for positioning two different layout patterns according to the present invention.

### DETAILED DESCRIPTION

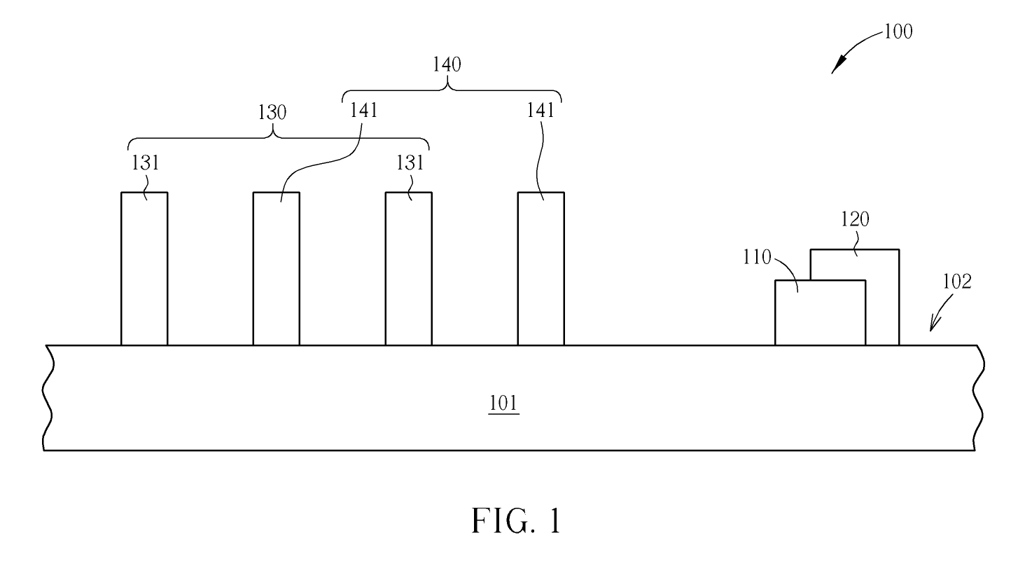

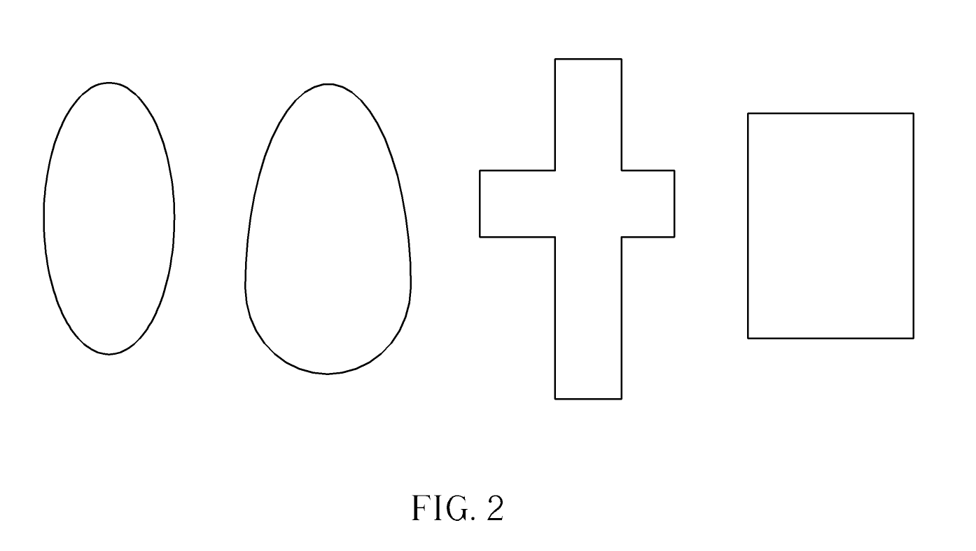

The present invention in a first aspect provides a novel overlay mark set. The overlay mark set is suitable for positioning two different layout patterns on a same surface of a substrate, particularly when using a pitch-doubling technique. FIGS. 1-2 illustrate the overlay mark set of the present invention. Please refer to FIG. 1. The overlay mark set 100 of the present invention includes a substrate 101, a first overlay mark 110 and a second overlay mark 120. The substrate 101 may be a semiconductor substrate, such as Si, or a multi-layer substrate. The multi-layer substrate may include previously formed elements, such as CMOS, contact plugs or interconnection.

The first overlay mark 110 is disposed on a surface 102 of the substrate 101. The first overlay mark 110 is formed along with a first layout pattern 130 on the surface 102 of the substrate 101 for representing the relative position of the first layout pattern 130. Accordingly, the first overlay mark 110 and the first layout pattern 130 may be of the same material.

The second overlay mark 120 is also disposed on the same surface 102 of the substrate 101. Like the first overlay mark 110, the second overlay mark 120 is formed along with a second layout pattern 140 on the surface 102 of the substrate 101 for representing the relative position of the second layout pattern 140. Similarly, the second overlay mark 120 and the second layout pattern 140 may be of the same material.

As shown in FIG. 1, one feature of the present invention is that the first overlay mark 110 is in direct contact with the second overlay mark 120. For example, the first overlay mark 110 may cover part of the second overlay mark 120 so the first overlay mark 110 is higher than the second overlay mark 120, or otherwise the second overlay mark 120 may cover part of the first overlay mark 110 so the second overlay mark 120 is higher than the first overlay mark 110, depending on which one is formed first. As shown in FIG. 2, the first overlay mark 110 or the second overlay mark 120 may be of various shapes provided they are not round, such as oval, polygonal or in the form of a cross.

In one embodiment of the present invention, the first overlay mark 110 is formed along with a previously formed layout pattern for representing the relative position of the previously formed layout pattern on the substrate 101, and the second overlay mark 120 is formed along with a currently formed layout pattern for representing the relative position of the currently formed layout pattern on the same substrate 101.

In a pitch-doubling method, a later formed layout pattern is formed in the neighborhood of a previously formed layout pattern and the later formed layout pattern must be aligned with the previously formed layout pattern to an extremely high precision. In such a scenario, the overlay mark set 100 of the present invention may exhibit a good utility.

In another embodiment of the present invention, the first layout pattern 130 and the second layout pattern 140 may be arranged in an alternate fashion. For example, as shown in FIG. 1, the first layout pattern 130 may include a plurality of first segments 131 and the second layout pattern 140 may include a plurality of second segments 141 so that the first segments 131 and second segments 141 are disposed in an alternate fashion. This arrangement is particularly common in the pitch-doubling method.

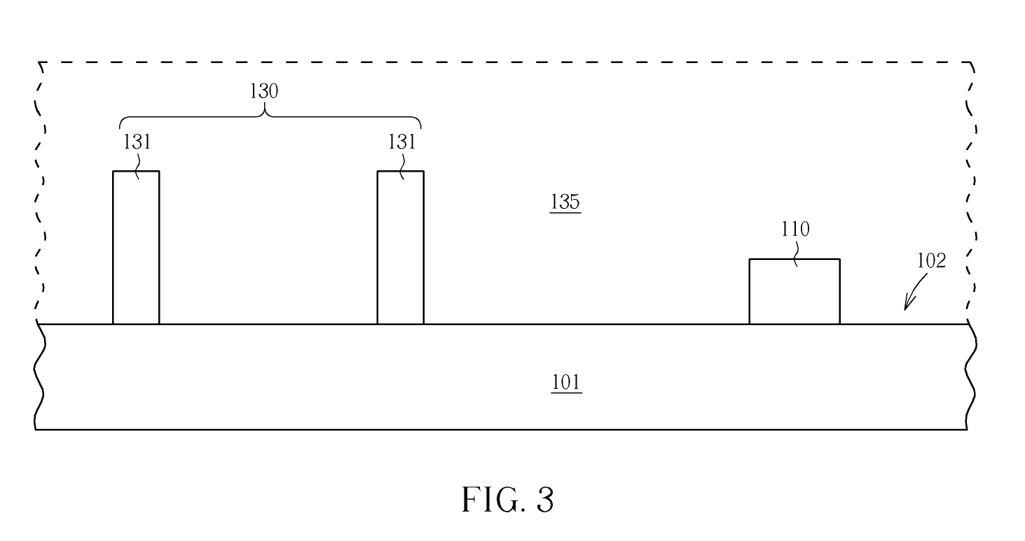

The present invention in a second aspect provides a method for positioning two different layout patterns on the same substrate, particularly when using a pitch-doubling technique. FIGS. 3-11 illustrate the methods for positioning two different layout patterns of the present invention. Please refer to FIG. 3. First, a substrate 101 is provided. The substrate 101 may be a semiconductor material such as Si and used in a pitch-doubling process. Second, a first layout pattern 130 and a first overlay mark 110 are together formed on the substrate 101. The first overlay mark 110 usually serves as the reference of the first layout pattern 130. The formation of the first layout pattern 130 and the first overlay mark 110 on the substrate 101 may be as follows. First, a first material layer 135 is formed on the substrate 101. The first material layer 135 may be a photoresist. Then, the first layout pattern 130 is transferred into the first material layer 135 by lithographic exposure and development. After the development, the first material layer 135 becomes the first layout pattern 130 with multiple first segments 131 of a specific pitch: for example, twice the needed pitch.

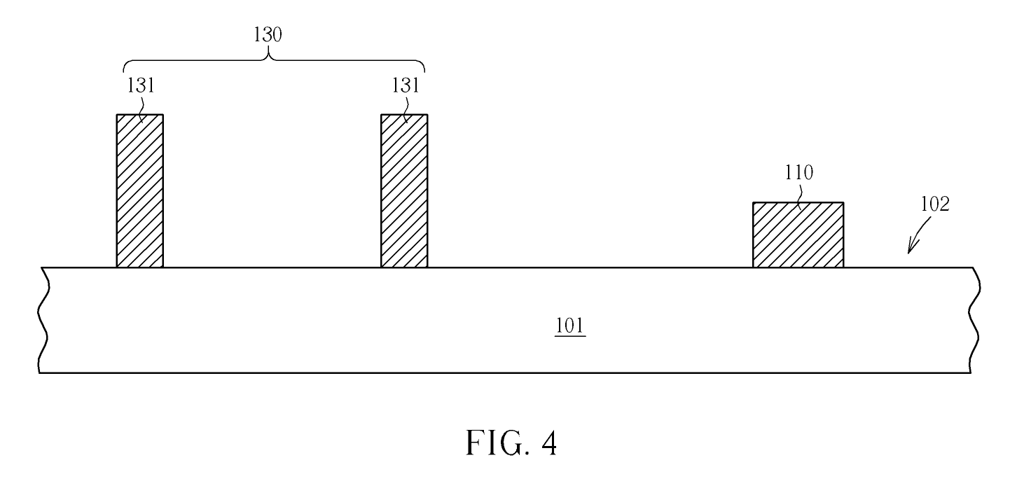

Optionally, as shown in FIG. 4, the first overlay mark 110 is processed. For example, the processing of the first overlay mark 110 acts to denature the first material layer 135 of the first overlay mark 110 so that the first material layer 135 and the first overlay mark 110 are no longer the same. In one embodiment of the present invention, the first overlay mark 110 may be processed by hard-baking

In another embodiment of the present invention, the method for positioning two layout patterns of the present invention may further include the optional step(s) of positioning the first overlay mark 110 in advance.

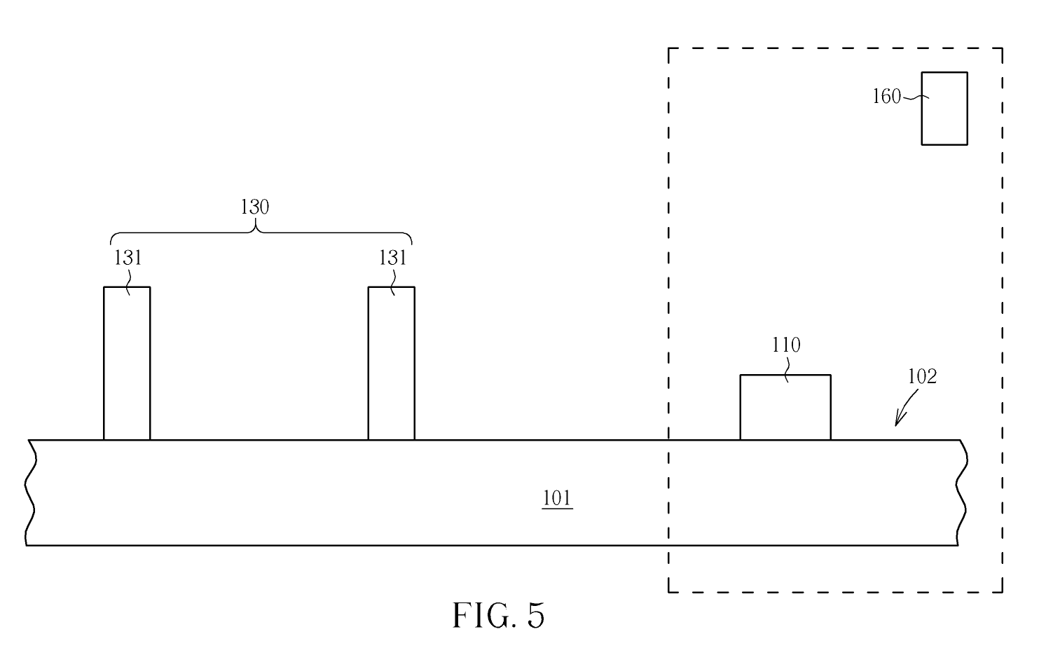

In one example, as shown in FIG. 5, the step of positioning the first overlay mark 110 may include recording the position of the first overlay mark 110 digitally. For example, the position of the first overlay mark 110 is recorded digitally by a computer 160 in accordance with its coordination.

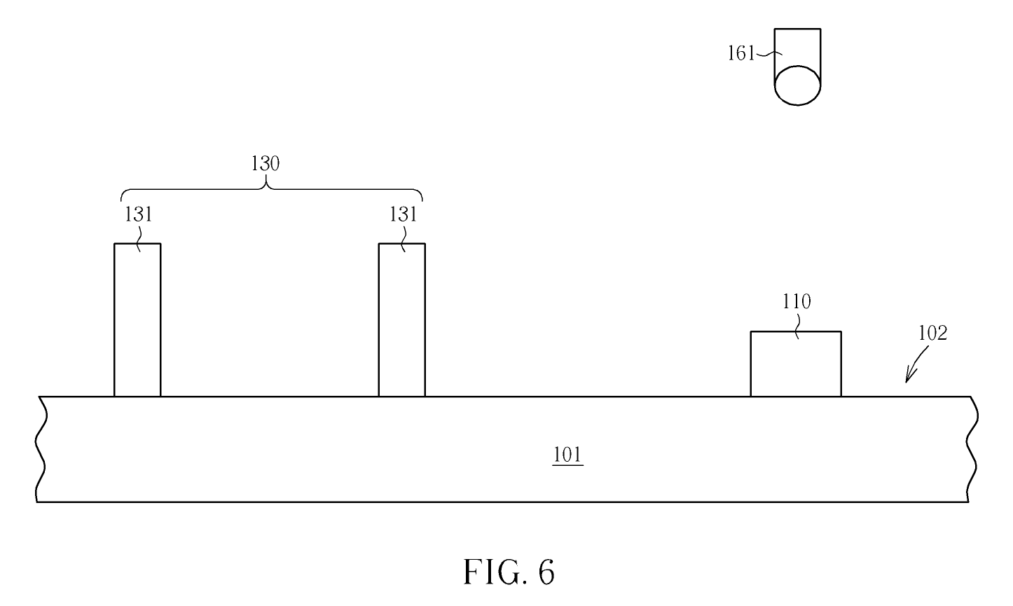

In another example, as shown in FIG. 6, the step of positioning the first overlay mark 110 includes taking an image of the first overlay mark 110 by an apparatus 161. For example, after the development or the hard-baking, a picture is taken by the apparatus 161 to record the shape and the location of the first overlay mark 110.

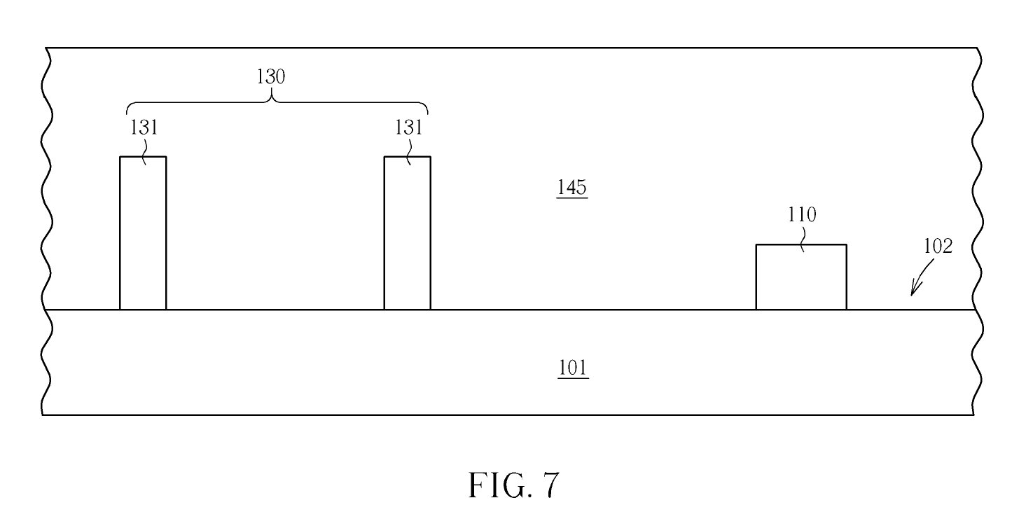

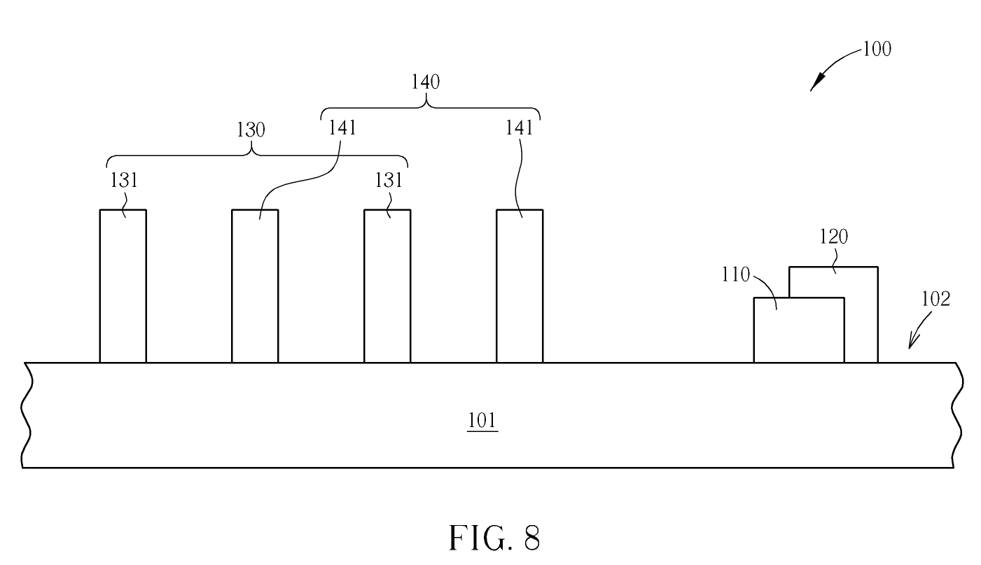

Next, a second layout pattern 140 and a second overlay mark 120 are formed together on the substrate 101 so that the second overlay mark 120 is in direct contact with the first overlay mark 110. The formation of the second layout pattern 140 and the second overlay mark 120 on the substrate 101 may be as follows. First, as shown in FIG. 7, a second material layer 145 is formed on the substrate 101 so that the second material layer 145 covers the first layout pattern 130. The first material layer 135 may also be a photoresist. Then, as shown in FIG. 8, the second layout pattern 140 is transferred into the second material layer 145 by lithographic exposure and development. After the development, the second material layer 145 becomes the second layout pattern 140 with multiple second segments 141 and the second overlay mark 120. The second overlay mark 120 is in direct contact with the first overlay mark 110. For example, the second overlay mark 120 may cover part of the first overlay mark 110. Similarly, the second layout pattern 140 may have multiple second segments 141 of a specific pitch so that the pitch of two adjacent first segments 131 and second segments 141 is the same according to requirements; the second layout pattern 140 does not need denaturing, however.

In one embodiment of the present invention, as shown in FIG. 8, the first layout pattern 130 and the second layout pattern 140 are disposed in alternate order. For example, the first segments 131 and second segments 141 are disposed in an alternate fashion.

The first overlay mark 110 and the second overlay mark 120 may not have the same height. For example, as shown in FIG. 8, the second overlay mark 120 may cover part of the first overlay mark 110 so the second overlay mark 120 is higher than the first overlay mark 110. Please refer to FIG. 2, which shows the first overlay mark 110 and the second overlay mark 120 may be of various shapes provided they are not round, such as oval, polygonal or in the shape of a cross.

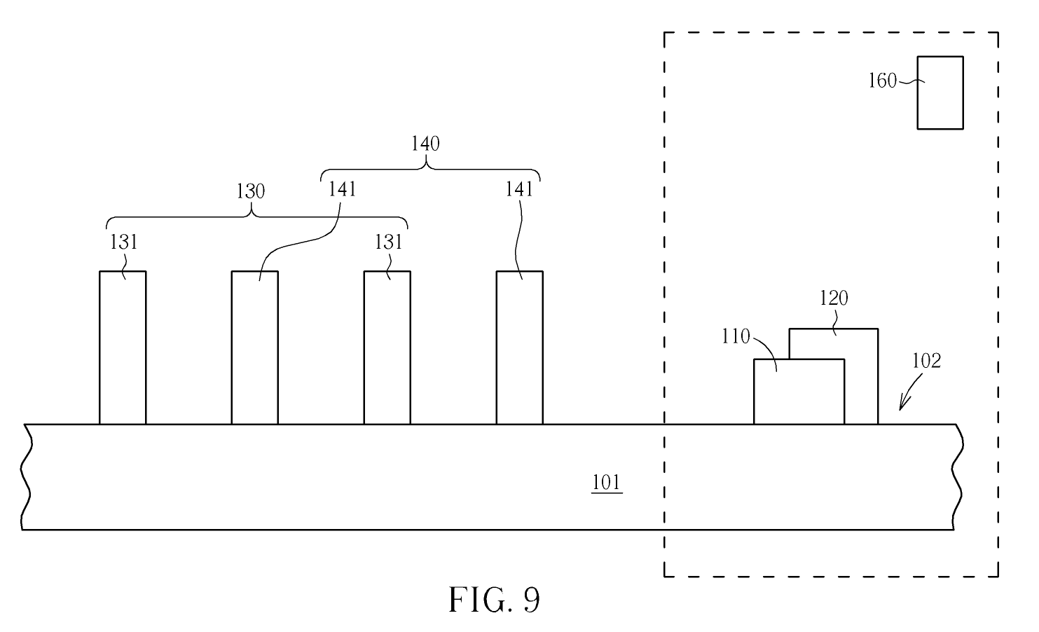

As shown in FIG. 9, the second overlay mark 120 is positioned and compared with the first overlay mark 110. There are various ways of carrying out the positioning and comparison. In a first example of the present invention, the positioning of the second overlay mark 120 may include the following steps.

The position of the second overlay mark 120 and the first overlay mark 110 is recorded digitally together by a computer 160 so the digital information represents both the second overlay mark 120 and the first overlay mark 110. Then, the position of the second overlay mark 120 and the first overlay mark 110 (namely, the digital information of the second overlay mark 120 and the first overlay mark 110) is compared with the digital information of the first overlay mark 110 recorded previously by the computer 160. Via subtraction of the first overlay mark 110, the overlay of the second layout pattern 140 with respect to the first layout pattern 130 is revealed. Generally, the smaller the amount of the second layout pattern 140 that remains, the better the overlay.

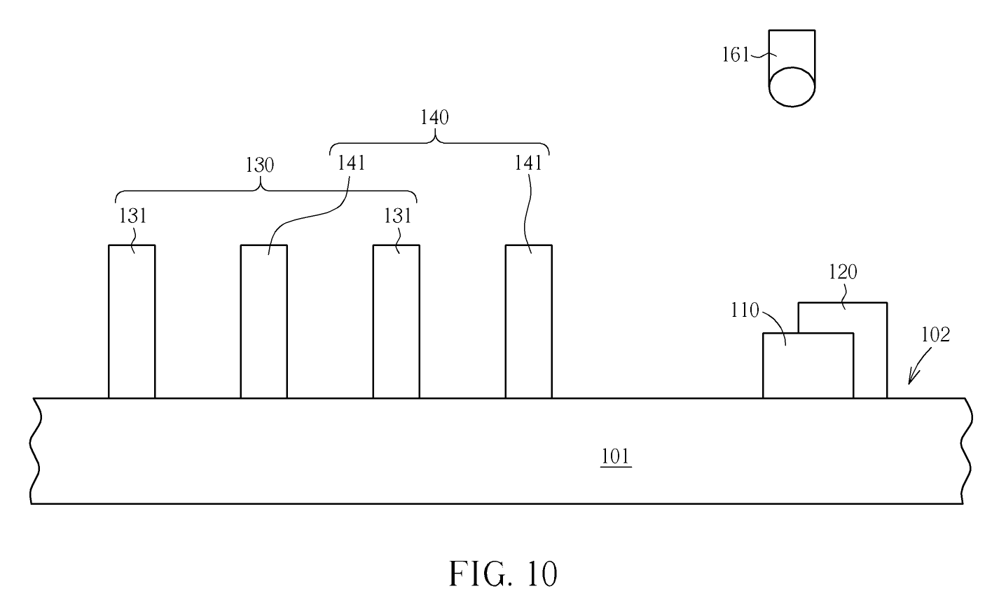

In a second example of the present invention, the positioning of the second overlay mark 120 may include the following steps. First, as shown in FIG. 6, an image of the first overlay mark 110 is taken alone by an apparatus 161. Then, as shown in FIG. 10, the image of the first overlay mark 110 and the second overlay mark 120 is taken again by the apparatus 161 and compared with the image of the first overlay mark 110 alone. Via this comparison, the overlay of the second layout pattern 140 with respect to the first layout pattern 130 is revealed. Generally, the more the second layout pattern 140 overlaps with the first overlay mark 110, the better the overlay.

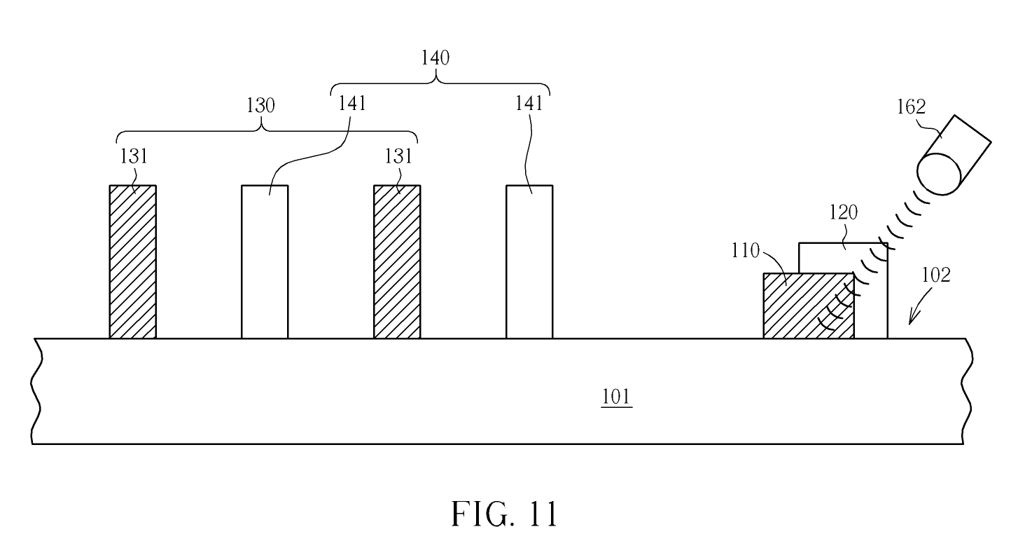

In a third example of the present invention, the positioning of the second overlay mark 120 may include the following steps. First, as shown in FIG. 11, the first overlay mark 110 and the second overlay mark 120 together are detected optically by an optical device 162 to obtain an optical data when the first overlay mark 110 is processed. When the first overlay mark 110 is previously processed and the second overlay mark 120 is not, the first overlay mark 110 and the second overlay mark 120 should be optically distinct. Then, the optical data is resolved to respectively position the first overlay mark 110 and the second overlay mark 120 and to determine the overlay of the second overlay mark 120 with respect to the first overlay mark 110.

Those skilled in the art will readily observe that numerous modifications and alterations of the device and method may be made while retaining the teachings of the invention.

What is claimed is:

1. An overlay mark set, comprising:
a substrate;
a first overlay mark representing a first layout pattern and disposed on said substrate; and
a second overlay mark representing a second layout pattern and disposed on said substrate, wherein said first overlay mark is in direct contact with said second overlay mark.

2. The overlay mark set of claim 1, further comprising:
said first layout pattern disposed on said substrate; and
said second layout pattern disposed on said substrate.

3. The overlay mark set of claim 2, wherein said first layout pattern and said second layout pattern are disposed in an alternate order.

4. The overlay mark set of claim 1, wherein said first overlay mark represents a previous layout pattern.

5. The overlay mark set of claim 4, wherein said second overlay mark represents a current layout pattern.

6. The overlay mark set of claim 1, wherein said second overlay mark is higher than said first overlay mark.

7. The overlay mark set of claim 1, wherein said first overlay mark is a polygon.

8. The overlay mark set of claim 1, wherein said first overlay mark is oval.

9. The overlay mark set of claim 1, wherein said second overlay mark is a polygon.

10. The overlay mark set of claim 1, wherein said second overlay mark is oval.

11. A method for positioning two layout patterns, comprising:
providing a substrate;
forming a first layout pattern and a first overlay mark on said substrate;
processing said first overlay mark;
forming a second layout pattern and a second overlay mark on said substrate, wherein said second overlay mark is indirect contact with said first overlay mark; and
positioning said second layout pattern.

12. The method for positioning two layout patterns of claim 11, wherein forming said first layout pattern and said first overlay mark on said substrate comprises:
forming a first material layer on said substrate; and
transferring said first layout pattern into said first material layer by exposure and development.

13. The method for positioning two layout patterns of claim 11,
wherein processing said first overlay mark comprises:
hard-baking said first overlay mark.

14. The method for positioning two layout patterns of claim 11, wherein forming said second layout pattern and said second overlay mark on said substrate comprises:
forming a second material layer on said substrate, wherein said second material layer covers said first layout pattern; and
transferring said second layout pattern into said second material layer by exposure and development.

15. The method for positioning two layout patterns of claim 11, wherein said first layout pattern and said second layout pattern are disposed in an alternate order.

16. The method for positioning two layout patterns of claim 11, further comprising:
positioning said first overlay mark.

17. The method for positioning two layout patterns of claim 16, wherein positioning said first overlay mark comprises:
recording the position of said first overlay mark digitally.

18. The method for positioning two layout patterns of claim 16, wherein positioning said first overlay mark comprises:
taking an image of said first overlay mark.

19. The method for positioning two layout patterns of claim 16, wherein positioning said second overlay mark comprises:
recording the position of said second overlay mark and said first overlay mark together digitally; and
comparing the position of said second overlay mark and said first overlay mark with the position of said first overlay mark alone.

20. The method for positioning two layout patterns of claim 18, wherein positioning said second overlay mark comprises:
taking an image of said first overlay mark and said second layout pattern together; and
comparing said image of said first overlay mark and said second overlay mark with said image of said first overlay mark alone.

21. The method for positioning two layout patterns of claim 11, wherein positioning said second overlay mark comprises:
detecting said first overlay mark and said second overlay mark together optically to obtain an optical data; and
resolving said optical data to respectively position said first overlay mark and said second overlay mark.
